(19) United States
(12) Patent Application Publication
(10) Pub. No.: US 2012/0055788 A1
(43) Pub. Date: Mar. 8, 2012

(54) TARGET FOR SPUTTERING

(75) Inventors: Hirohisa TAKAHASHI, Sammu-shi (JP); Sadayuki Ukishima, Sammu-shi (JP); Atsushi Ota, Sammu-shi (JP); Noriaki Tani, Sammu-shi (JP); Satoru Ishibashi, Sammu-shi (JP)

(73) Assignee: ULVAC, Inc., Chigasaki-shi (JP)

(21) Appl. No.: 13/297,920

(22) Filed: Nov. 16, 2011

Related U.S. Application Data
(62) Division of application No. 12/359,675, filed on Jan. 26, 2009.
Application No. 12/359,675 is a continuation of application No. PCT/JP07/64704, filed on Jul. 26, 2007.

(30) Foreign Application Priority Data
Jul. 28, 2006 (JP) 2006-205936

(51) Int. Cl. C23C 14/08; C23C 14/34

(52) U.S. Cl. 204/298.13

(57) ABSTRACT

A transparent electroconductive film having a low resistivity is provided. In a film-forming method of the present invention, a transparent electroconductive film is formed on a surface of a substrate by sputtering, in a vacuum atmosphere, a target in which ZnO is a main component and Al₂O₃ and TiO₂ are added to ZnO, and then the transparent electroconductive film is annealed by the heating thereof at a temperature of 250° C. or more and 400° C. or less. The resistivity of the obtained transparent electroconductive film is reduced because the film has ZnO as the main component and Al and Ti added therein. The transparent electroconductive film formed by the present invention is suitable as a transparent electrode for the FDP, etc.

This is a Continuation of International Application No. PCT/JP2007/064704 filed Jul. 26, 2007, which claims priority to Japan Patent Application No. 2006-205936, filed on Jul. 28, 2006. The entire disclosures of the prior applications are hereby incorporated herein by reference in their entireties.

### BACKGROUND

The present invention generally relates to a method for forming a film, and more particularly, to a method for forming a transparent electroconductive film.

As transparent electrodes to be employed in FDPs (Flat Display Panels) such as plasma display panels (PDPs) and liquid crystal panels, In—Sn—O type transparent electroconductive films (hereinafter referred to as ITO films) have been conventionally used. Since the price of indium had recently soared due to the depletion of indium sources, transparent electroconductive materials have been sought instead of ITO.

ZnO based materials have been examined as transparent electroconductive materials in place of the ITO. However, since ZnO has a high resistance, it is difficult to use ZnO alone as an electrode.

It is known that the resistivity is lowered by adding Al₂O₃ to ZnO. However, for example, when a film of a transparent electrode is formed by sputtering a target in which Al₂O₃ is added to ZnO, the resistivity of the transparent electrode is several times higher than that of the ITO film, and reduction in the resistivity is not practically sufficient.

Although the resistivity is generally lowered by heating treatment (annealing treatment) after the formation of the electroconductive film, the resistivity of the ZnO film to which Al₂O₃ was added was reversely increased by annealing in a high temperature range in the open air. See patent document No. JP A 11-236219.

### SUMMARY OF THE INVENTION

The present invention has been accomplished to solve the above problem, and is aimed at producing a transparent electroconductive film having a low resistivity by using an inexpensive and stably suppliable material.

In order to solve the above problem, the present invention is directed to a transparent electroconductive film-forming method for forming a transparent electroconductive film on a surface of an object to be film-formed by sputtering a target having a main component of ZnO in a vacuum atmosphere. The method includes: preliminarily adding a main addition oxide of Al₂O₃ into the target such that the number of atoms of a main addition element of Al is 1 or more and 10 or less per 100 atoms of Zn; selecting one or more kinds of secondary addition oxides from a secondary addition oxide group consisting of TiO₂, HfO₂ and ZrO₂; and adding the selected secondary addition oxide or oxides to the target such that the total number of atoms of Ti, Hf or Zr in the selected secondary addition oxide or oxides is 0.5 or more to 5 and less per 100 atoms of Zn.

The present invention is directed to the transparent electroconductive film-forming method, wherein after the transparent electroconductive film is formed, the transparent electroconductive film is annealed by heating it at a predetermined heating temperature, and the heating temperature is set at 250° C. or more and less than 500° C.

The present invention is directed to the transparent electroconductive film-forming method, wherein the transparent electroconductive film is heated in an open air atmosphere in the annealing.

The main component in the present invention means that the material as the main component is contained at 50 atom% or more of the total.

The present invention is provided as mentioned above, and since the Al₂O₃ (main addition oxide) and TiO₂ (secondary addition oxide) are added to the target, the transparent electroconductive film formed by the present invention has ZnO as the main component, and Al (main addition element) and Ti (secondary addition element) are added thereto.

When the secondary addition oxide added to the target is HfO₂, Hf is added to the transparent electroconductive film as the secondary addition element. When the secondary addition oxide is ZrO₂, Zr is added to the transparent electroconductive film as the secondary addition element. The secondary addition elements are so-called IVA (4A) group elements.

The resistivity of the ZnO film is lowered by the addition of Al, and distortion of ZnO crystals due to the addition of Al is mitigated by the addition of Ti. Therefore, the dopants (the total amount of Al and Ti) can be added at high concentrations. As a result, the resistivity of the transparent electroconductive film is lowered, as compared to a case in which no Al is added or in which only Al is added without the addition of Ti.

Further, an effect similar to that in the case of the addition of Ti alone is obtained when either one or both of Hf and Zr as the secondary addition elements are added in place of Ti or when either one or both of Hf and Zr are added together with Ti.

When Al is added alone to a film of ZnO as a donor (electron donor) at a high concentration, the electron mobility in crystals decreases, and Al, which is incorporated into the film as it is in an oxide state, increases. Consequently, the resistivity rises. According to the present invention, the reduction in the electron mobility is prevented by adding a different donor or different donors (such as, Ti) in addition to Al, so that the dopants can be added at high concentrations.

When the ZnO film to which Al and Ti are added is heated (annealed) after the film is formed by sputtering, the film is activated and the electric resistance decreases. Al is activated when Al is incorporated into the crystals in the ZnO film in the form of not an oxide but atoms. However, Al is inactivated by oxidation when the transparent electroconductive film is heated at a high temperature of 400° C. or more in the open air atmosphere.

Ti is activated at a higher temperature than Al, and is not oxidized even at a high temperature (for example, 450° C.) in the open air atmosphere. Therefore, even when the transparent electroconductive film of the present application is heated at a high temperature, the resistivity does not rise. Al is not oxidized in a vacuum.

Hf and Zr are activated at a higher temperature than Al, and not oxidized at high temperatures in the open air atmosphere. Therefore, a similar effect is obtained when either one or both of Hf and Zr are added as the secondary addition elements in place of Ti or when either one or both of Hf and Zr are added together with Ti.

It is presumed that when the target to which Al₂O₃ and TiO₂ are added is used in such a manner that the ratio of the number of the atoms of Al to that of Zn is 1% or more and 10% or less, and the ratio of the number of atoms of Ti to that of Zn is 0.5% or more and 5% or less, a transparent electroconductive film having high transparency and a low resistivity may be obtained.

The present invention can provide the transparent electroconductive film having a low resistivity by using the inexpensive and stably suppliable materials (such as, ZnO, Al₂O₃ and TiO₂) without the use of indium. Since the annealing treatment need not be performed in a vacuum atmosphere, the structure of a film-forming apparatus is simple, and the processing time in a vacuum chamber is shortened. It is presumed that when the film is obtained by heating, a similar or higher quality of the film is obtained. After the film is formed at such a temperature as causing small damage to a substrate, the resistance is lowered by the annealing treatment. Such a low temperature film-forming apparatus is simpler in structure than a high temperature film-forming apparatus.

### BRIEF DESCRIPTION OF THE DRAWINGS

FIG. 1 is a sectional view illustrating one example of a film-forming apparatus according to the present invention.

FIGS. 2(a) and (b) are sectional views illustrating film-forming steps of the transparent electroconductive film according to the present invention.

### DETAILED DESCRIPTION OF THE EMBODIMENTS

First, an example of steps for producing a target to be used in the present invention will be explained.

Three kinds of powdery oxides of ZnO, Al₂O₃ and TiO₂ are weighed; a mixed powder is prepared, in which ZnO is a main component and Al atoms and Ti atoms are contained at predetermined ratios relative to the number of atoms of Zn; and the mixed powder is preliminarily baked in a vacuum.

A mixture is prepared by adding and mixing water and a dispersant into the obtained baked material; and after the mixture is dried, it is preliminarily baked again in a vacuum. Then, after the baked material is ground and homogenized, it is molded in a plate-like form in a vacuum atmosphere, and a plate-like target is prepared by baking the molded body in the vacuum atmosphere.

This target has ZnO as the main component, to which Al₂O₃ and TiO₂ are added; and the ratios of the numbers of atoms of Zn, Al and Ti contained in the target are the same as in the above mixed powder.

Next, steps of forming a transparent electroconductive film by using the above target will be explained.

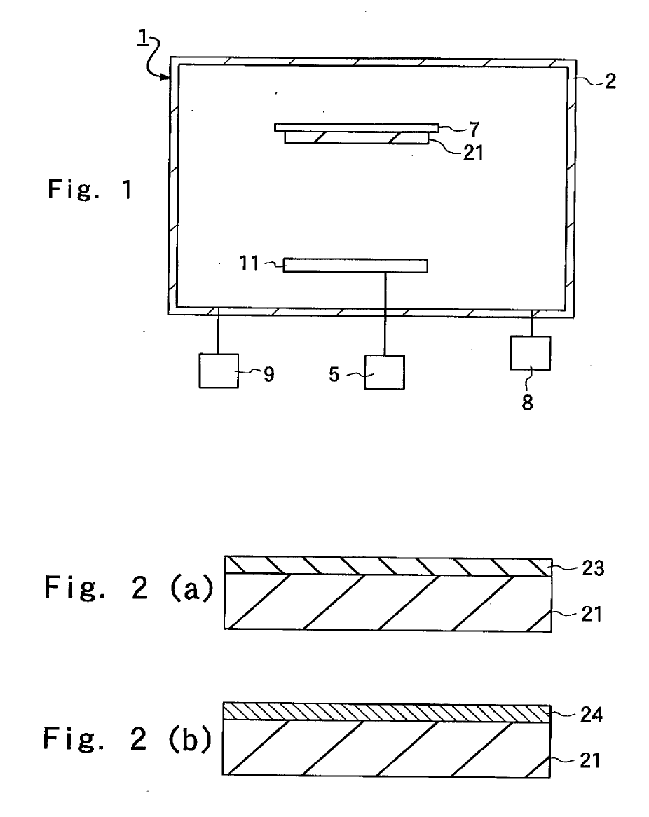

In FIG. 1, a reference numeral 1 generally indicates a film-forming apparatus to be used in the present invention. This film-forming apparatus 1 includes a vacuum chamber 2.

A vacuum evacuation system 9 and a sputtering gas feeding system 8 are connected to the vacuum chamber 2; and after the inside of the vacuum chamber 2 is evacuated to a vacuum by the vacuum evacuation system 9, a sputtering gas is fed into the vacuum chamber 2 from the sputtering gas feeding system 8, while the vacuum evacuation is being continued, thereby forming a film-forming atmosphere at a predetermined pressure.

The above-mentioned target 11 and a substrate holder 7 are arranged inside the vacuum chamber 2; and the substrate 21 as an object to be film-formed thereon is held by the substrate holder 7 in a state such that a surface thereof is directed so as to be opposed to the target 11.

The target 11 is connected to an electric power source 5 located outside the vacuum chamber 2. When a voltage is applied to the target 11 in a state such that the vacuum chamber 2 is set at a ground potential while the above film-forming atmosphere is being maintained, the target 11 is sputtered, and sputtered particles are discharged. A transparent electroconductive film 23 is grown on the surface of the substrate 21 such that in the transparent electroconductive film 23, ZnO is a main component and the ratios of the number of atoms of Zn, that of Al and that of Ti are the same as in the target 11 (See FIG. 2(a)).

The film formation is stopped at a time when the transparent electroconductive film 23 grows to a predetermined film thickness; and the substrate 21 is taken out from the film-forming apparatus 1 to the open air atmosphere.

The substrate 21 on which the transparent electroconductive film 23 is formed is carried into a heater (not shown); and the transparent electroconductive film 23 is annealed by heating at a predetermined annealing temperature in the open air atmosphere. In FIG. 2(b), a reference numeral 24 indicates the transparent electroconductive film which has performed the annealing treatment. Since the annealed transparent electroconductive film 24 has a low resistivity, it can be used as a transparent electrode for an FDP when that transparent electroconductive film 24 is patterned in a predetermined shape.

Unlike the ITO, the transparent electroconductive film of the present invention can be patterned even after the annealing treatment.

### EXAMPLE

After a target 11 was prepared under the following “Preparation condition”, a transparent electroconductive film 24 in Example 1 was formed on a surface of a substrate under the following “Film-forming condition” by using the target 11.

### <Preparation Condition>

Composition of a mixed powder: the number of atoms of Al=3 and that of Ti=1.5 (per 100 atoms of Zn)

Preliminary baking (first and second times): 750° C. in a vacuum atmosphere for 12 hours

Preparation of a mixture: mixed in a ball mill for 24 hours by using zirconia balls 10φ (particle diameter of 10 mm)

Drying of the mixture: dried in an oven for 48 hours

Grinding: manually ground so as to become not more than 750 μm in particle diameter by using a mortar

Molding and baking of the target: molded and baked at 1000° C. for 150 minutes in a vacuum by hot press

Size of the target: 4 inches in diameter

### <Film-Forming Condition>

Temperature of a substrate: 160° C.

Film thickness: 200 nm (2000 Å)

Sputtering gas: Ar

Flow rate of Ar: 200 sccm

Pressure of a film-forming atmosphere: 0.4 Pa

Voltage applied to the target: 0.8 kW (DC power source)

Annealing temperature: 200° C. or more and 400° C. or less (in the open air atmosphere)

### <Resistivity Measurement>

As to the transparent electroconductive film 24 in Example 1 after the annealing treatment, the resistivity was measured by a 4-probe low resistivity meter.

A transparent electroconductive film in the Comparative Example was prepared under the same condition as in the above Example 1 except that a target was used, in which ZnO was a main component and 2 wt % of Al₂O₃ was added (no Ti contained) ; and the resistivity of the transparent electroconductive film was also measured under the same condition as in the Example 1. The following Table 1 shows the measurement results thereof together with the annealing temperatures.

TABLE 1
Table 1: Measurement of resistivity

| | Resistivity [μΩ · cm] | | | | | |
|---|---|---|---|---|---|---|
| | Before | After annealing in open air for 1 hour | | | | |
| Target | annealing | 200° C. | 250° C. | 300° C. | 350° C. | 400° C. |
| Example 1 | 2179 | 809 | 543 | 469 | 476 | 608 |
| Comparative | 1085 | 686 | 645 | 672 | 675 | 590000 |
| Example | | | | | | |

As the transparent electrode for the FDP, the resistivity is preferably around 500 μΩ·cm or less. The measurement results are as shown in Table 1 such that since the resistivity is around 500 μΩ·cm when the annealing temperature is 250° C. or more and 400° C. or less, the annealing temperature is preferably 250° C. or more and 400° C. or less. Further, the above results show that the film obtained in the Example 1 is transparent and is optically and electrically suitable as a transparent electrode.

On the other hand, the resistivity in the Comparative Example largely exceeded 600 μΩ·cm even when the annealing temperature was varied; and particularly with respect to the film annealed at the annealing temperature of 400° C. or more, the oxidation of the transparent electroconductive film proceeded, and the degradation of the resistance was distinguished. To the contrary, the resistivity of the transparent electroconductive film 24 in the Example 1 did not significantly increase even when the annealing temperature was 400° C.

The above results show that if the transparent electroconductive film formed by sputtering the target, in which ZnO is a main component and Al₂O₃ and TiO₂ are added to ZnO, is annealed at a temperature of 250° C. or more and 400° C. or less, the film suitable for the transparent electrode can be obtained.

The above explanation has been made for the case where Ar gas is used as the sputtering gas, but the invention is not limited thereto. As the sputtering gas, a Xe gas, a Ne gas or the like can also be used.

The method for producing the target 11 is not particularly limited, and the target 11 to be used in the present application can be produced by a variety of producing methods that are ordinarily employed.

When the annealing treatment is performed in the vacuum atmosphere, the resistivity becomes lower than when it is performed in the open air atmosphere. However, since a vacuum chamber to be exclusively used for the annealing treatment needs to be prepared for annealing in the vacuum atmosphere, the film-forming apparatus becomes complicated and expensive. Moreover, as the processing time inside the vacuum chamber becomes longer due to the annealing time, the time required for the formation of a film on a single substrate is longer than in the case where the annealing is performed in the open air atmosphere.

As described above, according to the present invention, even when the annealing treatment is done in the open air atmosphere, the resistivity becomes practically sufficiently lower for the transparent electrode, so that the annealing treatment is preferably performed in the open air atmosphere.

The transparent electroconductive films 24 formed by the present invention can be used as transparent electrodes for various display devices such as FED (Field Emission Display) or the like besides the transparent electrodes for the PDP and the liquid crystal panels. Since no problem occurs in the producing process in the cases of the FED and the PDP even if the annealing temperature is set at a high temperature of 250° C. or more, the invention of this application is particularly suitable for the production of the transparent electrodes in these display apparatuses.

If the optimum ranges of an addition amount of Al₂O₃ (the ratio of the number of atoms of Al with respect to that of Zn) and an addition amount of TiO₂ (the ratio of the number of atoms of Ti with respect to that of Zn) to be respectively added to the target are found, it is estimated that even if the annealing temperature is less than 250° C., a low resistivity can be attained.

In the above, the case where TiO₂ is added to the target as the secondary addition oxide has been explained, but the present invention is not limited thereto.

### Examples 2 to 6

Targets 11 in the Examples 2 to 6 were prepared under the same condition as in the above Example 1 except that addition amounts of Al₂O₃ and the secondary addition oxides (TiO₂, HfO₂ or ZrO₂) were changed. After a transparent electroconductive film 23 was formed under the same condition as in the above Example 1 by using each target 11, an annealed transparent electroconductive film 24 was obtained by heating in a temperature range of 200° C. to 500° C. in the open air atmosphere.

Resistivities of the annealed transparent electroconductive films 24 and the transparent electroconductive films 23 before the annealing were measured by the method described in the above “Resistivity measurement”.

The targets 11 of the Examples 2 to 6 are composed of ZnO, Al₂O₃, TiO₂, HfO₂, ZrO₂, and the following Table 2 shows the relationships among the numbers of the respective components per 100 of the components composing the target 11 (figures in a column of ratios of components of target), heating temperatures and resistance values.

TABLE 2
Table 2: Ratios of components of target, heating temperature and resistivity

| | Ratios of | | | | | Resistivity (μΩ · cm) | | | | | | | |
|---|---|---|---|---|---|---|---|---|---|---|---|---|---|
| | components of target | | | | | Before | Heating in open air for 1 hour | | | | | | |
| | ZnO | Al₂O₃ | TiO₂ | HfO₂ | ZrO₂ | annealing | 200° C. | 250° C. | 300° C. | 350° C. | 400° C. | 450° C. | 500° C. |
| Example 2 | 97.0 | 1.5 | 1.5 | 0 | 0 | 986 | 690 | 503 | 395 | 373 | 381 | 857 | O.L. |
| Example 3 | 94.0 | 3.0 | 3.0 | 0 | 0 | 889 | 711 | 529 | 411 | 398 | 402 | 788 | O.L. |
| Example 4 | 91.0 | 4.5 | 4.5 | 0 | 0 | 937 | 734 | 548 | 389 | 391 | 371 | 751 | O.L. |
| Example 5 | 95.5 | 1.5 | 0 | 3.0 | 0 | 1168 | 916 | 677 | 504 | 492 | 520 | 1249 | O.L. |
| Example 6 | 95.5 | 1.5 | 0 | 0 | 3.0 | 1159 | 814 | 625 | 487 | 478 | 475 | 987 | O.L. |

“O.L” in the above Table 2 denotes “over the range”, which shows that the resistivity is so high that it cannot be measured by the above-mentioned low resistivity meter.

The above Table 2 shows that when the targets 11 in the Examples 2 to 6 are used, the results of the Table 2 exhibit “over the range” at the heating temperature of 500° C.; and thus, the low resistivities can be obtained at 200° C. or more and less than 500° C. When the transparent electroconductive films formed by using the target in the above Comparative Example were heated at 450° C. or 500° C., the resistivities were over the range.

The numbers of atoms of Al, Hf, Ti and Zr contained in the respective components per 100 atoms of Zn in the target 11 were determined from the ratios of the components of the targets shown in the above Table 2, and they were taken as the contents of the elements. The contents of the elements in the Examples 2 to 6 are as given in the following Table 3.

TABLE 3
Contents of elements

| | Contents of elements | | | | |
|---|---|---|---|---|---|
| | Zn | Al | Ti | Hf | Zr |
| Example 2 | 100 | 3.09 | 1.55 | 0 | 0 |
| Example 3 | 100 | 6.38 | 3.19 | 0 | 0 |
| Example 4 | 100 | 9.89 | 4.95 | 0 | 0 |
| Example 5 | 100 | 3.14 | 0 | 3.14 | 0 |
| Example 6 | 100 | 3.14 | 0 | 0 | 3.14 |

From the above Table 3 and the above Example 1, in the Examples 1 to 6, the number of the atoms of the main addition element (Al) is in a range of 3.09 or more and 9.89 or less relative to 100 atoms of Zn; and the number of the atoms of the secondary addition element (Ti, Hf, Zr) is in a range of 1.5 or more and 4.95 or less relative to 100 atoms of Zn.

Therefore, it is understood that if the number of the atoms of the main addition element is 1 or more and 10 or less relative to 100 atoms of Zn and the number of the atoms of the secondary addition element is 0.5 or more and 5 or less relative to 100 atoms of Zn, the transparent electroconductive film 24 optically and electrically suitable for the transparent electrode can be formed.

Although the case has been explained above in which only one kind of the secondary addition oxides was added to the target 11, the invention is not limited thereto. Two or more kinds of the secondary addition oxides from the secondary addition oxide group consisting of TiO₂, HfO₂ and ZrO₂ may be added to the same target 11. In this case, the total number of the atoms of the secondary addition elements (Ti, Hf and Zr) of the secondary addition oxides added to the target 11 is set at 0.5 or more and 5 or less relative to 100 atoms of Zn.

Heating of the transparent electroconductive film 23 is not limited to the heating in the open air atmosphere; and the transparent electroconductive film 23 maybe heated during the film-formation in the vacuum atmosphere, or in a case subsequent to the formation of the transparent electroconductive film 23, it may be heated in the vacuum atmosphere.

Main causes for the resistance degradation are that the ionized carrier is oxidized, the oxygen-lacking state cannot be maintained due to the oxidation, and the carrier does not function as an n-type semiconductor. Therefore, it is clear that for the purpose of reducing the resistance, the high-temperature heating in the open air atmosphere is the severest condition, as compared to the case of the heating during the film formation and the case of the heating in the vacuum atmosphere.

No resistance degradation occurs, even when the annealing temperature in the vacuum atmosphere is set higher than the annealing temperature in the open air atmosphere (for example, 500° C. or more). When the heating is performed during the film formation, the quality of the film can be obtained, which is equivalent to or higher than the annealing in the open air atmosphere.

1. (canceled)

2. (canceled)

3. (canceled)

4. A target for sputtering, comprising
a main component of ZnO characterized in that a main addition oxide of Al₂O₃ is added such that the number of atoms of a main addition element of Al is in a range of 1 or more and 10 or less per 100 atoms of Zn, one or more kinds of secondary addition oxides are selected from a secondary addition oxide group consisting of HfO₂ and ZrO₂, and the selected secondary addition oxide or oxides is added such that the total number of atoms of Hf or Zr in the selected secondary addition oxide or oxides is in a range of 0.5 or more and 5 or less per 100 atoms of Zn.
